(19) United States
(12) Patent Application Publication
(10) Pub. No.: US 2026/0307354 A1
(43) Pub. Date: Oct. 8, 2026

(54) PRESSING MECHANISM, WORKPIECE HOLDING MECHANISM, AND PROCESSING APPARATUS

(71) Applicant: Ushio Denki Kabushiki Kaisha, Tokyo (JP)

(72) Inventor: Kohei FUJII, Tokyo (JP)

(73) Assignee: Ushio Denki Kabushiki Kaisha, Tokyo (JP)

(21) Appl. No.: 19/637,579

(22) Filed: Apr. 2, 2026

(30) Foreign Application Priority Data
Apr. 3, 2025 (JP) 2025-061676

(51) Int. Cl. B30B 1/32; B30B 9/28

(52) U.S. Cl. CPC B30B 1/32; B30B 9/28

(57) ABSTRACT

A pressing mechanism includes a support, at least one fluid cylinder, a warpage correction portion, and a tensile portion. The support is disposed above a stage on which a workpiece is placed. The at least one fluid cylinder includes a main body fixed to the support, and a piston rod that protrudes downward from the main body and moves up and down according to a pressure of a fluid supplied to the main body. The warpage correction portion is attached to the piston rod and presses the workpiece against the stage from above by lowering of the piston rod to correct warpage of the workpiece. The tensile portion generates a tensile force between the support and the warpage correction portion along with the lowering of the piston rod.

### CROSS REFERENCE TO RELATED APPLICATIONS

This application claims the benefit of Japanese Priority Patent Application JP 2025-061676 filed on Apr. 3, 2025, the entire contents of which are incorporated herein by reference.

### BACKGROUND

The present invention relates to a pressing mechanism for holding a workpiece, a workpiece holding mechanism, and a processing apparatus.

When a workpiece on a vacuum suction stage has warpage, a gap is generated between the stage and the workpiece, which may make it difficult to properly vacuum-suction the workpiece. In this regard, technologies of correcting warpage of a workpiece to be flat by pressing the workpiece from above have been developed. For example, Japanese Patent Application Laid-open No. 2003-234392 describes a method of pressing a semiconductor wafer from above with a pressing plate and making the semiconductor wafer flat to hold it by suction onto a holding table.

### SUMMARY

If the warpage of the workpiece is corrected, it is thought that an excessive force acts on the workpiece depending on the method of pressing the workpiece and thus damages the workpiece. Thus, it is desirable to provide a technology capable of suitably controlling a warpage correcting force applied to the workpiece.

In view of the circumstances as described above, it is desirable to provide a pressing mechanism, a workpiece holding mechanism, and a processing apparatus that are capable of suitably controlling a warpage correcting force applied to a workpiece.

According to an embodiment of the present invention, there is provided a pressing mechanism including a support, at least one fluid cylinder, a warpage correction portion, and a tensile portion.

The support is disposed above a stage on which a workpiece is placed.

The at least one fluid cylinder includes a main body fixed to the support, and a piston rod that protrudes downward from the main body and moves up and down according to a pressure of a fluid supplied to the main body.

The warpage correction portion is attached to the piston rod and presses the workpiece against the stage from above by lowering of the piston rod to correct warpage of the workpiece.

The tensile portion generates a tensile force between the support and the warpage correction portion along with the lowering of the piston rod.

In the pressing mechanism, the warpage correction portion that corrects warpage of the workpiece placed on the stage from above is driven by the piston rod of the fluid cylinder. Further, the pressing mechanism includes a tensile portion that generates a tensile force between the support, to which the main body of the fluid cylinder is fixed, and the warpage correction portion. This makes it possible to reduce the load of the warpage correction portion and the piston rod, the load acting on the workpiece in addition to the thrust of the fluid cylinder. As a result, it is possible to suitably control the warpage correcting force applied to the workpiece.

The tensile portion may be configured such that a combined force of a load of a movable portion including the piston rod and the warpage correction portion and the tensile force is zero at a reference position below a standby position of the warpage correction portion with the piston rod being raised.

The reference position may be a position at which a lower end of the warpage correction portion reaches a height of a surface of the stage, the height including a thickness of the workpiece.

The tensile portion may include at least one tensile spring that is connected to the support and the warpage correction portion.

The at least one tensile spring may include a plurality of tensile springs. In this case, the plurality of tensile springs may be disposed to be rotationally symmetric to a central axis of the warpage correction portion.

The at least one fluid cylinder may include a single fluid cylinder.

The pressing mechanism may further include a guide portion that causes the warpage correction portion to slide relative to the support along a moving direction of the piston rod.

The at least one fluid cylinder may include an air cylinder.

The support may be a plate-like member. In this case, the at least one fluid cylinder may be disposed such that the main body protrudes from a lower surface of the support.

According to another embodiment of the present invention, there is provided a workpiece holding mechanism including a stage and a pressing mechanism.

On the stage, a workpiece is placed.

The pressing mechanism includes a support disposed above the stage, at least one fluid cylinder including a main body fixed to the support and a piston rod that protrudes downward from the main body and moves up and down according to a pressure of a fluid supplied to the main body, a warpage correction portion that is attached to the piston rod and presses the workpiece against the stage from above by lowering of the piston rod to correct warpage of the workpiece, and a tensile portion that generates a tensile force between the support and the warpage correction portion along with the lowering of the piston rod.

According to still another embodiment of the present invention, there is provided a processing apparatus including a stage, a pressing mechanism, and a processing section.

On the stage, a workpiece is placed.

The pressing mechanism includes a support disposed above the stage, at least one fluid cylinder including a main body fixed to the support and a piston rod that protrudes downward from the main body and moves up and down according to a pressure of a fluid supplied to the main body, a warpage correction portion that is attached to the piston rod and presses the workpiece against the stage from above by lowering of the piston rod to correct warpage of the workpiece, and a tensile portion that generates a tensile force between the support and the warpage correction portion along with the lowering of the piston rod.

The processing section performs predetermined processing on the workpiece held on the stage.

As described above, according to the present invention, it is possible to suitably control a warpage correcting force applied to a workpiece. Note that the effects described herein are not necessarily limited and may be any effect described in the present disclosure.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a schematic view showing a configuration example of an exposure apparatus according to an embodiment of the present invention;

FIG. 2 is a schematic view showing a configuration example of a pressing mechanism;

FIG. 3 is a schematic view showing a configuration example of a pressing mechanism described as a comparative example;

FIG. 4 is a graph showing characteristics of a warpage correcting force by the pressing mechanism described as the comparative example;

FIG. 5 is a schematic view showing an operation example of the pressing mechanism according to this embodiment;

FIG. 6 is a graph showing characteristics of a warpage correcting force by the pressing mechanism according to this embodiment;

FIG. 7A is a perspective view showing a specific configuration example of a workpiece holding mechanism;

FIG. 7B is a perspective view showing a specific configuration example of the workpiece holding mechanism;

FIG. 8A is a side view showing a specific configuration example of the pressing mechanism; and

FIG. 8B is a side view showing a specific configuration example of the pressing mechanism.

### D ETAILED D ESCRIPTION OF EMBODIMENTS

Hereinafter, an embodiment according to the present invention will be described with reference to the drawings.

### Configuration of Exposure Apparatus

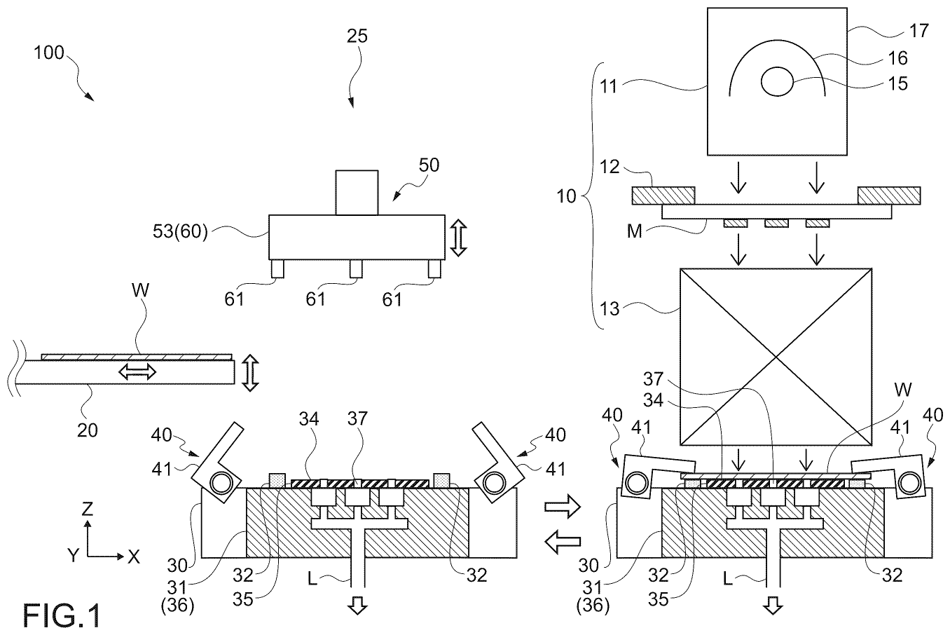

FIG. 1 is a schematic view showing a configuration example of an exposure apparatus according to an embodiment of the present invention. An exposure apparatus 100 is an apparatus that exposes a plate-like workpiece W to light. The exposure apparatus 100 includes an exposure section 10, a workpiece handler 20, and a workpiece holding mechanism 25 including a workpiece stage 30.

The workpiece W is, for example, an organic substrate or a glass substrate and is placed on the workpiece stage 30. Hereinafter, in the workpiece W, the side facing toward the workpiece stage 30 will be described as a back side of the workpiece W, and the side opposite from the workpiece stage 30 will be described as a front side of the workpiece W. The main surface on the front side of the workpiece W is an exposure surface on which exposure is to be performed. The exposure surface of the workpiece W loaded into the exposure apparatus 100 is coated with a sensitive material such as photoresist.

As the workpiece W, for example, a rectangular substrate in which each side has a length of approximately 500 mm is used. In addition, a relatively thin workpiece W having a thickness of approximately 0.2 mm can also be used. As a matter of course, the shape, planar size, and thickness of the workpiece W are not limited to the above example. In this embodiment, the case where the planar shape of the workpiece W is rectangular will be mainly described, but the present invention is also applicable to a workpiece W having a circular shape or a polygonal shape.

In the following, directions orthogonal to each other on the plane (a suction surface 34 to be described later) along the workpiece stage 30 on which the plate-like workpiece W is placed will be referred to as an X direction and a Y direction. In addition, a direction orthogonal to the XY plane will be descried as a Z direction. FIG. 1 is a schematic view of the exposure apparatus 100 as viewed from the Y direction. The XY plane is, for example, set as a horizontal plane, and the Z direction is set as a vertical direction. Note that the orientation in which the exposure apparatus 100 is used, or the like is not limited and can be discretionally set.

The exposure section 10 exposes a pattern onto the workpiece W held on the workpiece stage 30. As shown in FIG. 1, the exposure section 10 includes a light irradiation section 11, a mask M, a mask stage 12, and a projection optical system 13.

The light irradiation section 11 emits exposure light. The light irradiation section 11 includes a lamp 15, a mirror 16, and a lamp house 17. The lamp 15 is a light source for exposure that emits exposure light including ultraviolet rays. The mirror 16 reflects the exposure light emitted from the lamp 15 in a predetermined emission direction. The lamp house 17 is an enclosure that houses the lamp 15 and the mirror 16. Here, a case will be described, in which the light source of the light irradiation section 11 is the lamp 15; however, examples of the light source to be used may include a light-emitting diode (LED) and a laser light source. Additionally, the wavelength and bandwidth of the exposure light are also not limited.

A pattern such as a circuit pattern to be exposed (transferred) onto the workpiece W is formed on the mask M. The mask stage 12 holds the mask, onto which the pattern has been formed, on an optical path of the exposure light. The projection optical system 13 projects the exposure light that has been transmitted through the mask M onto the flat plate-like workpiece W. For example, the projection optical system 13 is configured as a reduction optical system in which the pattern of the mask M is reduced in size to form an image on the surface of the workpiece W. Note that in this embodiment the case where the mask M and the mask stage 12 are included in the exposure section 10 will be described, but the present invention is also applicable to a case where the mask M and the mask stage 12 are not included. For example, the present invention may also be applied to, for example, a direct imaging (DI) exposure apparatus that directly draws a wiring pattern by scanning of laser light.

In this embodiment, the exposure of a pattern onto the workpiece W is an example of predetermined processing, the exposure section 10 is an example of a processing section that performs predetermined processing on a workpiece held on a stage, and the exposure apparatus 100 is an example of a processing apparatus. The present invention can be applied to a processing apparatus that performs any processing such as film-forming and polishing, other than the exposure apparatus 100 as shown in FIG. 1.

The workpiece handler 20 is a transport apparatus that transports the workpiece W to the workpiece stage 30. In this embodiment, the workpiece handler 20 is configured to support the workpiece W from the back side. In this case, the workpiece W transported by the workpiece handler 20 is placed on the workpiece stage 30 via a delivery pin (not shown) or the like, the delivery pin being provided to the workpiece stage 30 and having a raising and lowering function. In addition to the above, the specific configuration of the workpiece handler 20, the method of delivering the workpiece W, and the like are not limited, and any mechanism capable of placing the workpiece W on the workpiece stage 30 may be used.

The workpiece stage 30 is a stage on which the workpiece W is placed. The workpiece stage 30 is configured as a vacuum suction stage that vacuum-suctions the workpiece W. The workpiece stage 30 includes a suction portion 31 and a seal member 32. The suction portion 31 includes a suction plate 35 having a suction surface 34 on which the workpiece W is vacuum-suctioned, and a base 36 that supports the suction plate 35. The workpiece W is placed on the workpiece stage 30 with the back surface facing the suction surface 34. The suction surface 34 (suction plate 35) includes a plurality of vacuum suction holes 37. Additionally, each vacuum suction hole 37 is connected to piping L for vacuum evacuation via a void formed in the base 36. For example, when the workpiece W is vacuum-suctioned, the piping L is connected to a vacuum pump. Further, when the vacuum suction for the workpiece W is released, gas (air etc.) for breaking the vacuum atmosphere is supplied to the piping L.

The seal member 32 is a seal member (vacuum seal) made of an elastic body. The seal member 32 is disposed around the suction surface 34 such that the workpiece W hides at least part of the seal member 32 in plan view when the suction surface 34 is viewed from above. In other words, the seal member 32 is disposed at a position surrounding the suction surface 34 and below the workpiece W and is configured to come into contact with the back surface of the workpiece W. Providing the seal member 32 makes it less likely to generate a gap on the back surface side of the workpiece W and makes it possible to suppress the leakage of the vacuum atmosphere.

In this embodiment, the workpiece stage 30 is connected to a moving mechanism (not shown) and moves between a delivery position and an exposure position for the workpiece W. At the delivery position, the workpiece W is delivered between the workpiece handler 20 and the workpiece stage 30. At the exposure position, the workpiece W is disposed immediately below the projection optical system 13. For the moving mechanism, for example, a linear surface motor using magnetic levitation, a mechanism that moves the workpiece stage 30 along a rail, and a mechanism that holds and moves the workpiece stage 30 using an arm or the like are used. Other configurations of the moving mechanism are not limited.

The workpiece holding mechanism 25 includes the workpiece stage 30 described above, a clamp mechanism 40, and a pressing mechanism 50. The clamp mechanism 40 is a mechanism that clamps the workpiece W to the workpiece stage 30 by a clamp portion 41 provided to the workpiece stage 30. The pressing mechanism 50 is a mechanism that corrects warpage of the workpiece W by pressing the workpiece W from above onto the workpiece stage 30. In the workpiece holding mechanism 25, a holding operation (vacuum suction or clamp operation) for holding the workpiece W onto the workpiece stage 30 is performed with the workpiece W being pressed by the pressing mechanism 50. In the following, a specific configuration of the pressing mechanism 50 will be described.

### Configuration of Warpage Correction Mechanism

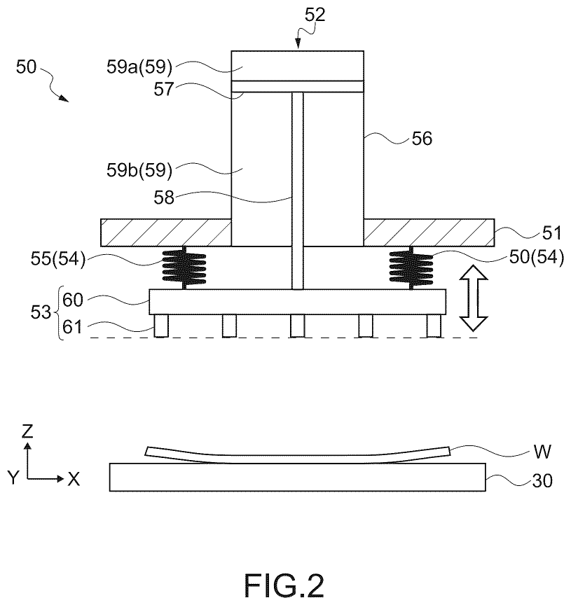

FIG. 2 is a schematic view showing a configuration example of the pressing mechanism. In FIG. 2, it is assumed that the pressing mechanism 50 is in a standby state. The standby state is a state before an operation of pressing the workpiece W against the workpiece stage 30 by the pressing mechanism 50 (hereinafter, referred to as pressing operation) is performed.

When the pressing mechanism 50 is in a standby state, it is assumed that the workpiece W is warped as shown in FIG. 2. The warpage of the workpiece W is caused by performing, in the previous process, a step of laminating a plurality of layers (multilayering), a step of heating the workpiece W, and other steps. For example, if the workpiece W has a rectangular shape in which each side has a length of approximately 500 mm, warpage of approximately 6 mm generally occurs, although it depends on the thickness of the workpiece W. If the workpiece W is warped in this manner, the suction holes are not closed, which makes it difficult to vacuum-suction the workpiece W onto the workpiece stage 30.

The pressing mechanism 50 is a mechanism provided to eliminate such warpage of the workpiece W, and corrects the warpage of the workpiece W to be flat by pressing the workpiece W from above. The basic configuration of the pressing mechanism 50 will be described here. As shown in FIG. 2, the pressing mechanism 50 includes a support 51, an air cylinder 52, a warpage correction portion 53, and a tensile portion 54.

The support 51 is a member disposed above the workpiece stage 30 and supports the entire pressing mechanism 50. A structural member such as a plate member or a frame can be used as the support 51.

The air cylinder 52 is a drive mechanism that uses pressure of compressed gas (typically, compressed air) to perform linear motion. The air cylinder 52 includes a cylinder main body 56, a piston 57, and a piston rod 58. In this embodiment, the air cylinder 52 is an example of a fluid cylinder.

The cylinder main body 56 is a container that forms a cylindrical cylinder chamber 59 (pressure chamber) into which compressed air is supplied. The cylinder chamber 59 is typically configured as a cylindrical space. The cylinder main body 56 includes a partition member (so-called cylinder tube) that constitutes the cylinder chamber 59. In addition, the cylinder main body 56 includes as appropriate a cover member that covers the partition member, a member for attaching the cylinder main body 56, and the like.

As shown in FIG. 2, the cylinder main body 56 is fixed to the support 51. Specifically, the cylinder main body 56 is attached to the support 51 with the piston rod 58 facing downward. In this embodiment, the cylinder main body 56 corresponds to the main body of the fluid cylinder.

The piston 57 is a plate-like member disposed so as to be orthogonal to the central axis of the cylinder chamber 59 and partitions the cylinder chamber 59. Typically, a disc-shaped piston 57 that is inscribed in the cylindrical cylinder chamber 59 is used. In the following, the upper cylinder chamber 59 partitioned by the piston 57 will be referred to as an upper cylinder chamber 59a, and the lower cylinder chamber 59 will be referred to as a lower cylinder chamber 59b.

In the cylinder main body 56, compressed air is supplied to the upper cylinder chamber 59a and the lower cylinder chamber 59b independently. Note that in order to adjust the pressure of the compressed air, a manual pressure regulator may be used, or an electropneumatic regulator that controls pressure according to an input pressure value, or the like may be used. Use of an electropneumatic regulator makes it possible to set thrust of the air cylinder 52, for example, from a control screen of a PC or the like.

The piston rod 58 is a rod-like member connected to the piston 57 and functions as an operation subject of the linear motion of the air cylinder. The piston rod 58 is connected to the lower side of the piston 57 and disposed to penetrate the lower surface of the cylinder main body 56. The air cylinder 52 is disposed, for example, such that the piston rod 58 linearly moves substantially along the Z-direction (typically, vertical direction). Note that the air cylinder 52 may be disposed, for example, such that the operation direction of the piston rod 58 is slightly tilted from the Z-direction.

For example, when the pressure of the upper cylinder chamber 59a is higher than the pressure of the lower cylinder chamber 59b, the piston rod 58 is lowered. Conversely, when the pressure of the upper cylinder chamber 59a is lower than the pressure of the lower cylinder chamber 59b, the piston rod 58 rises. Thus, the piston rod 58 protrudes downward from the cylinder main body 56 and moves up and down according to the pressure of the fluid (compressed air) supplied to the cylinder main body 56.

In the pressing mechanism 50, the thrust of the piston rod 58 is a force to press the workpiece W. Therefore, the air cylinder 52 is selected as appropriate, for example, according to a correcting force necessary to correct the warpage of the workpiece W. For example, if a larger correcting force is required, an air cylinder 52 with a larger diameter of the cylinder chamber 59 only needs to be selected. Conversely, if a smaller correcting force is required, an air cylinder 52 with a smaller diameter of the cylinder chamber 59 only needs to be selected.

The warpage correction portion 53 is a member that comes into contact with the workpiece W from above to correct its warpage. Specifically, the warpage correction portion 53 is attached to the piston rod 58 and presses the workpiece W against the workpiece stage 30 from above by lowering of the piston rod 58, to thereby correct the warpage of the workpiece W.

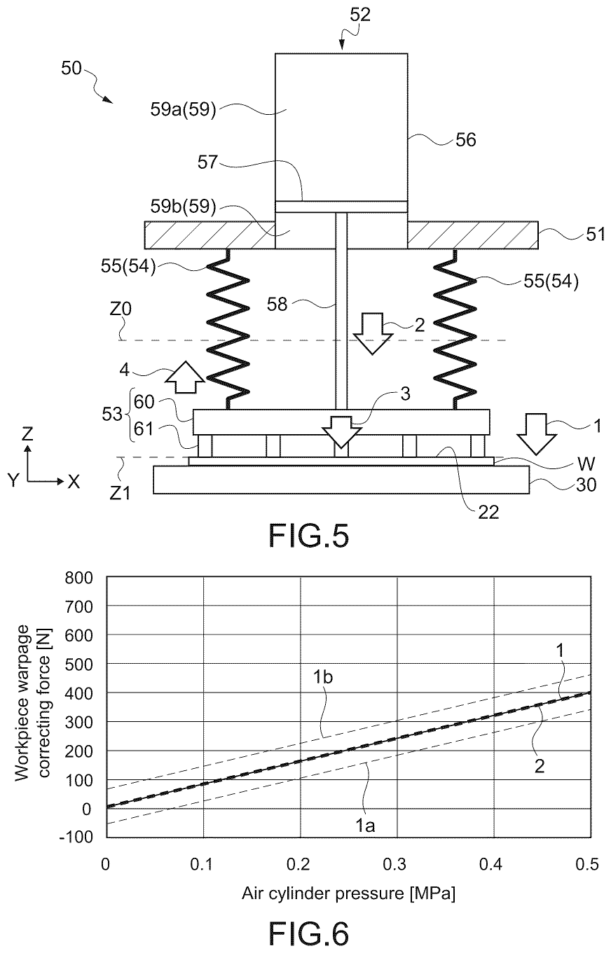

The warpage correction portion 53 includes a support frame 60 and a plurality of pushers 61. The support frame 60 is a plate-like member having a planar shape that is the same shape and size as the workpiece W. The tip (lower end) of the piston rod 58 is connected to the upper surface of the support frame 60. The plurality of pushers 61 are components that come into contact with the workpiece W and are provided to protrude from the lower surface of the support frame 60 while being spaced apart from each other. Note that a state in which the warpage correction portion 53 is lowered will be descried later with reference to FIG. 5.

The tensile portion 54 generates a tensile force between the support 51 and the warpage correction portion 53 along with the lowering of the piston rod 58. In other words, the tensile portion 54 is a mechanism that exerts a force (tensile force) to pull up the warpage correction portion 53 toward the support 51 when the piston rod 58 is lowered and the warpage correction portion 53 is then lowered.

In this embodiment, at least one tensile spring 55 connected to the support 51 and the warpage correction portion 53 is used as the tensile portion 54. In other words, one end of the tensile spring 55 is connected to the support 51, and another end thereof is connected to the warpage correction portion 53. For example, when the piston rod 58 is lowered from the state shown in FIG. 2, the tensile spring 55 is extended to generate a restoring force. This restoring force is a tensile force to pull up the warpage correction portion 53. In this embodiment, a case where a plurality of tensile springs 55 are provided will be mainly described. Note that the number of tensile springs 55 is not limited, and it is also possible to provide only one tensile spring 55, for example.

### Load of Pressing Operation

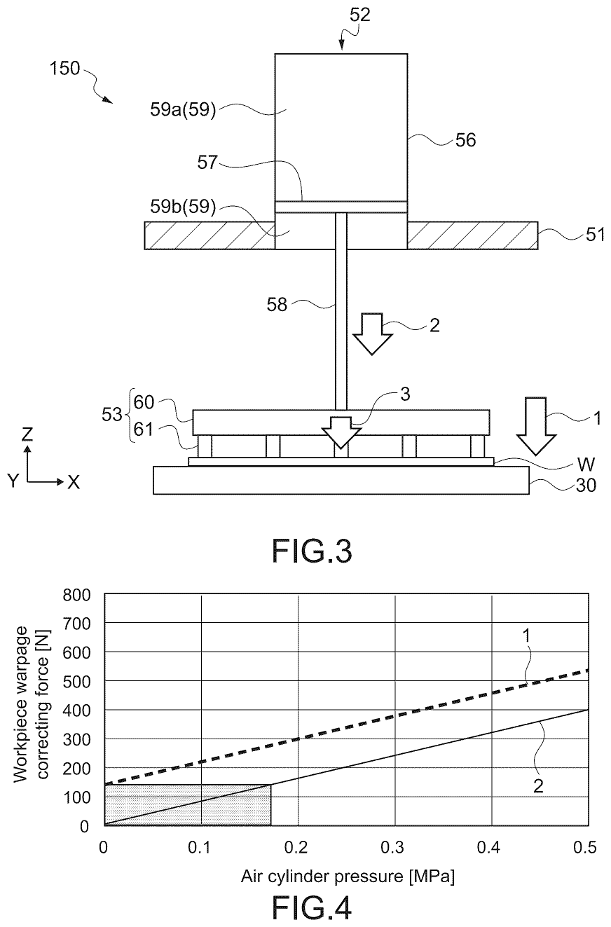

FIG. 3 is a schematic view showing a configuration example of a pressing mechanism described as a comparative example. A pressing mechanism 150 as a comparative example shown in FIG. 3 is a pressing mechanism 50 shown in FIG. 2 without the plurality of tensile springs 55 (tensile portion 54). In the following, a warpage correcting force 1 acting on the workpiece W when the pressing operation is performed by the pressing mechanism 150 of the comparative example will be described.

The pressing operation is an operation of increasing the pressure of the upper cylinder chamber 59a of the air cylinder 52 to lower the piston rod 58 and pressing the warpage correction portion 53 (the plurality of pushers 61) against the upper surface of the workpiece W. In this case, for example, the lower cylinder chamber 59b is opened to the atmosphere, and compressed air is supplied such that the pressure of the upper cylinder chamber 59a is higher than atmospheric pressure. Thus, as shown in FIG. 3, during the pressing operation, downward thrust 2 corresponding to the pressure of the upper cylinder chamber 59a acts on the piston rod 58. Note that the thrust 2 is typically a force proportional to the pressure of the upper cylinder chamber 59a.

In addition, the pressing mechanism 150 is configured to press the workpiece W from above. Thus, the workpiece W is subjected to a load 3 of a movable portion that is integrally lowered as viewed from the cylinder main body 56 (support 51). The load 3 of the movable portion is a downward force (self-weight of the movable portion) corresponding to the mass of the movable portion caused by gravity. In the example shown in FIG. 3, the piston 57, the piston rod 58, and the warpage correction portion 53 correspond to the movable portion of the pressing mechanism 150.

A warpage correcting force 1 applied to the workpiece W (the force of the pressing mechanism 150 to press the workpiece W against the workpiece stage 30) during the pressing operation is a combined force of the thrust 2 of the air cylinder 52 and the load 3 from the warpage correction portion 53 and the like, which have been described above. For example, assuming that the Z-direction serving as the operation direction of the air cylinder 52 is the vertical direction, the value obtained by adding the magnitude of the thrust 2 F_{cylinder} and the magnitude of the load 3 F_{load} is the magnitude of the warpage correcting force 1 F_{correction} (=F_{cylinder}+F_{load}). Note that it is assumed here that a frictional force between the piston 57 and the inner wall of the cylinder chamber 59, a frictional force between the piston rod 58 and the cylinder main body 56, and the like are sufficiently smaller than the load 3 and the thrust 2 and can be ignored.

FIG. 4 is a graph showing characteristics of the warpage correcting force by the pressing mechanism described as a comparative example. The horizontal axis of the graph represents the air cylinder pressure [MPa], and the vertical axis represents the workpiece warpage correcting force [N]. Note that the air cylinder pressure is the pressure in the upper cylinder chamber 59a when the piston rod 58 is lowered.

In FIG. 4, the warpage correcting force 1 generated by the pressing mechanism 150 of the comparative example shown in FIG. 3 is plotted by a thick dotted line. In addition, the thrust 2 generated by the air cylinder 52 is plotted by a thin solid line. The thrust 2 shown in FIG. 4 is, for example, the force resulting solely from the air cylinder pressure excluding the load 3 of the piston rod 58 and the like. This can be regarded as the thrust 2 that is obtained, for example, when the air cylinder 52 is disposed horizontally.

As shown in FIG. 4, if the air cylinder pressure is zero, the thrust 2 of the air cylinder is also zero. Therefore, if the warpage correcting force 1 includes only the thrust 2 of the air cylinder, the warpage correcting force 1 can be adjusted from 0 Pa with the air cylinder pressure alone.

However, as described with reference to FIG. 3, in the pressing mechanism 150, the load 3 of the movable portion is added to the warpage correcting force 1. Thus, even if the air cylinder pressure is 0 Pa (i.e., the thrust 2 is 0 N), the warpage correcting force 1 will not be 0.

For example, assuming that the mass of the movable portion of the pressing mechanism 150 is 15 kg, the load 3 of the movable portion is approximately 150 N. In this case, as shown in FIG. 4, the warpage correcting force 1 when the air cylinder pressure is 0 Pa is approximately 150 N, and the warpage correcting force 1 can only be adjusted from 150 N or more. In other words, even if the air cylinder pressure is adjusted within the pressure range that achieves the thrust 2 at 150 N or less (the range indicated by the hatching in FIG. 4), it is not possible to generate a warpage correcting force 1 of 150 N or less.

In such a manner, in the pressing mechanism 150 of the comparative example, which includes only the air cylinder 52 as a drive portion, not only the thrust 2 of the air cylinder 52 but also the load 3 of the movable portion are added to the warpage correcting force 1, resulting in an excessive warpage correcting force 1 for the workpiece W. Thus, there is a possibility that the workpiece W may be damaged by the pressing operation depending on the workpiece W. In addition, since the warpage correcting force 1 is difficult to adjust from 0, applicable workpieces W are limited.

### Load and Tensile Force

FIG. 5 is a schematic view showing an operation example of the pressing mechanism according to this embodiment. FIG. 5 shows a state of the pressing operation using the pressing mechanism 50 shown in FIG. 2. In the pressing operation, as in the case of FIG. 3, the air cylinder pressure is increased to lower the piston rod 58, so that the warpage correction portion 53 is pressed against the upper surface of the workpiece W.

During the pressing operation, downward thrust 2 is generated with respect to the piston rod 58. In addition, a load 3 corresponding to the mass of the movable portion including the piston 57, the piston rod 58, and the warpage correction portion 53 is generated. The generation of the thrust 2 and the load 3 is the same as in the case of FIG. 3.

Further, in the pressing mechanism 50 according to this embodiment, the lowering of the piston rod 58 extends the plurality of tensile springs 55 and generates a tensile force 4. Here, the tensile force 4 is a combined force obtained by adding up the restoring forces of the individual tensile springs 55.

As shown in FIG. 5, the tensile force 4 is an upward force in the Z-direction to pull up the warpage correction portion 53. Therefore, the tensile force 4 functions as a force to reduce the thrust 2 and load 3 downward in the Z-direction.

The warpage correcting force 1 applied to the workpiece W during the pressing operation of the pressing mechanism 50 is a combined force of the thrust 2 of the air cylinder 52, the load 3 from the warpage correction portion 53 and the like, and the tensile force 4 generated by the plurality of tensile springs 55, which have been described above. For example, assuming that the Z-direction serving as the operation direction of the air cylinder 52 is the vertical direction, the value obtained by adding the magnitude of the thrust 2 F_{cylinder} and the magnitude of the load 3 F_{load} and then subtracting the magnitude of the tensile force 4 (Fₜₑₙₛᵢₗₑ) therefrom is the magnitude of the warpage correcting force 1 F_{correction} (=F_{cylinder}+F_{load}−Fₜₑₙₛᵢₗₑ).

In such a manner, the pressing mechanism 50 has a structure that cancels out the self-weight of the movable portion including the warpage correction portion 53 when the warpage correction portion 53 is pressed against the workpiece W from above. Specifically, the load 3 of the movable portion is canceled out by the tensile force 4 using the tensile springs 55, the tensile force 4 working in a return direction when the tensile springs 55 are extended. Note that canceling out the load 3 in the present disclosure is to cause a force to act in a direction that decreases the component of the load 3, and includes both cases where the load 3 is completely canceled and where the load 3 is partially canceled. This reduces the effect of the load 3, which is a fixed value, and increases the proportion of the thrust 2, which is an adjustable force, in the warpage correcting force 1. As a result, the controllability of the warpage correcting force 1 can be enhanced.

Here, the tensile force 4 generated by the plurality of tensile springs 55 during the pressing operation will be described. The plurality of tensile springs 55 (tensile portion 54) are configured such that a combined force of the load 3 of the movable portion including the piston rod 58 and the warpage correction portion 53 and the tensile force 4 is zero at a reference position Z1 located below a standby position Z0 of the warpage correction portion 53 with the piston rod 58 being raised.

FIG. 5 shows the standby position Z0 and the reference position Z1 on the basis of a position of the lower end of the warpage correction portion 53 in the Z-direction (lower ends of the plurality of pushers 61) being in contact with the workpiece W.

For example, the air cylinder 52 can take two states: a state with the piston rod 58 being lowered (a state with the piston rod 58 being extended); and a state with the piston rod 58 being raised (a state with the piston rod 58 being contracted). Of those states, the state with the piston rod 58 being raised is a standby state in which the pressing mechanism 50 is not performing the pressing operation. The standby position Z0 represents the height position of the warpage correction portion 53 in the standby state.

The reference position Z1 is a height position that is set lower than the standby position Z0. Therefore, in the pressing mechanism 50, the spring constants of the plurality of tensile springs 55 are set such that the load 3 and the tensile force 4 are balanced at the reference position Z1 lower than the standby position Z0. This means that in the process of lowering the warpage correction portion 53 from the standby position Z0, the load 3 of the movable portion exerts an action to extend the tensile springs 55 until the warpage correction portion 53 reaches the reference position Z1. This eliminates the need to unnecessarily increase the thrust 2 of the air cylinder 52 in order to extend the tensile springs 55.

In this embodiment, the reference position Z1 is set at the position where the lower end of the warpage correction portion 53 reaches the height of the surface of the workpiece stage 30 including the thickness of the workpiece W. Here, the height of the surface of the workpiece stage 30 including the thickness of the workpiece W is, for example, the height position of the surface of the workpiece W with the workpiece W being properly vacuum-suctioned (hereinafter, referred to as a reference surface position 22 of the workpiece W).

FIG. 6 is a graph showing characteristics of the warpage correcting force by the pressing mechanism according to this embodiment. In FIG. 6, the warpage correcting force 1 generated by the pressing mechanism 50 shown in FIG. 5 is plotted by a thick dotted line, and the thrust 2 of the air cylinder 52 is plotted by a thin solid line.

As described above, in the pressing mechanism 50, in a state where the tips of the pushers 61 reach the reference surface position 22 of the workpiece W, that is, in a state where the piston rod 58 of the air cylinder 52 is extended to reach the stroke end, the load 3 is completely canceled out by the tensile force 4. Thus, the warpage correcting force 1 acting on the workpiece W is substantially equal to the thrust 2 of the air cylinder 52.

As a result, as shown in FIG. 6, the graph of the warpage correcting force 1 passes through the origin and increases in proportion to the air cylinder pressure. This is obtained by, for example, shifting downward the warpage correcting force 1, which has been shifted upward by the load 3 of the movable portion in FIG. 4, so as to pass through the origin by introducing the tensile force 4.

This makes it possible to control the warpage correcting force 1 to be generated in the range from 0 N to 150 N, which is not possible in FIG. 4. This makes it possible to set the warpage correcting force 1 for the workpiece W to a small value, thereby avoiding a situation in which the workpiece W is damaged by the pressing operation. As a result, it is possible to apply optimum warpage correcting forces 1 to workpieces W of various strengths, especially to workpieces W of small strength, respectively, and it is possible to properly correct the warpage of each workpiece W or the like.

Note that the reference position Z1 may be set higher than the reference surface position 22 of the workpiece W. In this case, during the pressing operation, the tensile force 4 acts as a force to lower the thrust 2, so that a warpage correcting force 1a with the thrust 2 being shifted downward is achieved as shown in FIG. 6. For example, there may be a case where the thrust 2 at a lower pressure is unstable due to the characteristics of the air cylinder 52, the characteristics of a pressure adjusting mechanism of compressed air, and the like. In such a case, the thrust 2 is lowered by the tensile force 4 as described above, which makes it possible to adjust the warpage correcting force 1a in a higher pressure range and to set a force applied to the workpiece W with high accuracy.

In addition, the reference position Z1 may be set lower than the reference surface position 22 of the workpiece W. In this case, during the pressing operation, the load 3 is not completely canceled out by the tensile force 4, so that a warpage correcting force 1b with the thrust 2 being shifted upward is achieved as shown in FIG. 6. Note that the warpage correcting force 1b is closer to a pure thrust 2 than the warpage correcting force 1 obtained without introducing the tensile force 4 shown in FIG. 4. For example, if the pressure of the compressed air is low and a sufficient thrust 2 is difficult to obtain, the load 3 can be used to increase the thrust 2. This allows a necessary warpage correcting force 1 to be achieved while keeping equipment costs low.

As described above, the reference position Z1 does not necessarily have to be set to the reference surface position 22 of the workpiece W. For example, the reference position Z1 only needs to be set as appropriate according to the accuracy and strength of the required warpage correcting force 1, and the tensile springs 55 only need to be selected as appropriate on the condition that a reaction force during extension at the reference position Z1 is equal to the self-weight of the movable portion.

### Specific Configuration Example of Workpiece Holding Mechanism

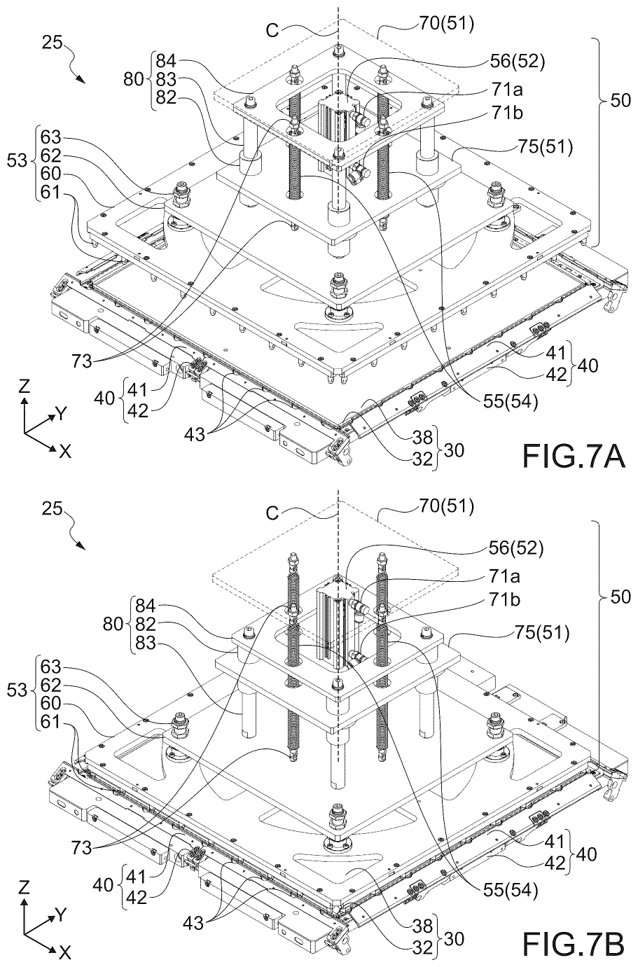

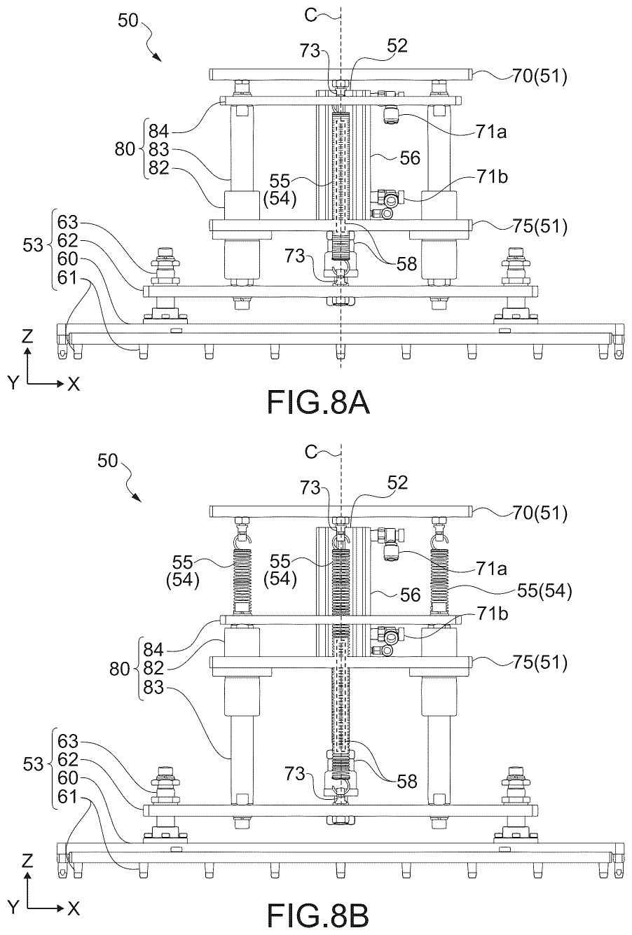

FIGS. 7A and 7B are perspective views each showing a specific configuration example of the workpiece holding mechanism. FIGS. 8A and 8B are side views each showing a specific configuration example of the pressing mechanism. FIGS. 7A and 8A show a standby state in which the warpage correction portion 53 is pulled up to the standby position. FIGS. 7B and 8B show a state in which the warpage correction portion 53 is lowered and the pressing operation is performed. Hereinafter, specific configuration examples of the pressing mechanism 50, the workpiece stage 30, and the clamp mechanism 40 will be described.

### Pressing Mechanism

As shown in FIG. 7A, the pressing mechanism 50 includes a top plate 70, a support plate 75, the air cylinder 52, the plurality of tensile springs 55, the warpage correction portion 53, and a guide portion 80.

The top plate 70 is a plate-like member provided at the top of the pressing mechanism 50. Note that FIGS. 7A and 7B illustrate the top plate 70 as a transparent member by the dotted line. The support plate 75 is a plate-like member provided below and spaced apart from the top plate 70. The workpiece stage 30 is disposed at a predetermined distance below the support plate 75. Note that the support plate 75 is provided with through-holes for passing the piston rod 58 of the air cylinder 52 and the plurality of tensile springs 55 therethrough. The top plate 70 and the support plate 75 are non-movable members whose positions do not change before and after the pressing operation, and function as the support 51 that supports the entire pressing mechanism 50.

The air cylinder 52 includes the cylinder main body 56, the piston rod 58, an upper connection port 71a, and a lower connection port 71b. Note that the piston rod 58 is not visible in FIG. 7A (and FIG. 7B). In addition, a portion of the piston rod 58 is schematically illustrated by a dotted line in FIG. 8A (and FIG. 8B).

The cylinder main body 56 is a columnar member whose cross section is a substantially square. A cylindrical cylinder chamber is formed inside the cylinder main body 56. The piston rod 58 is provided to the lower end of the cylinder main body 56 to protrude therefrom. In addition, the lower end of the cylinder main body 56 is fixed to the center of the upper surface of the support plate 75 using screws or predetermined fixtures as appropriate.

As shown in FIG. 8A, the tip (lower end) of the piston rod 58 is connected to an intermediate frame 62 of the warpage correction portion 53 to be described later. Thus, when the piston rod 58 is lowered as shown in FIG. 8B, the entire member connected to the intermediate frame 62 is lowered. The upper connection port 71a and the lower connection port 71b are connection ports that supply compressed air to the upper cylinder chamber and the lower cylinder chamber inside the cylinder main body 56 and exhaust the upper and lower cylinder chambers.

As shown in FIGS. 7A and 7B, in this embodiment, the four tensile springs 55 are provided as the plurality of tensile springs 55. For example, a coil spring spirally wound with a metal wire such as a stainless steel wire can be used as each of the tensile spring 55. Each tensile spring 55 is hooked and fixed to a pair of spring posts 73 provided on the lower surface of the top plate 70 and the upper surface of the intermediate frame 62, respectively.

In this embodiment, the plurality of tensile springs 55 are disposed to be rotationally symmetrical to the central axis C of the warpage correction portion 53. Here, the central axis C of the warpage correction portion 53 is, for example, an axis along the Z-direction passing through the center of gravity of the warpage correction portion 53. For example, the drive axis of the piston rod 58 is set to coincide with the central axis C.

Here, the four tensile springs 55 are disposed to be rotationally symmetrical to the central axis C at intervals of 90°. This makes it possible to regard a combined restoring force (tensile force 4) of the tensile springs 55 as a force acting on the center of gravity of the warpage correction portion 53 in effect, and to properly cancel out the load 3 of the warpage correction portion 53 and the like. In addition, it is also possible to suppress a situation in which the warpage correcting force 1 is biased in the XY plane due to the bias in the restoring force of each tensile spring 55.

In addition, the plurality of tensile springs 55 are configured to have their natural length or be in an extended state at the standby position of the warpage correction portion 53 with the piston rod 58 being raised (the standby state shown in FIGS. 7A and 8A).

In general, it is better to install the tensile springs 55 in a slightly extended state to eliminate a clearance caused by the extension and contraction operation and stabilize the extension and contraction operation. On the other hand, if the tensile springs 55 are overly extended at the standby position, a relatively large tensile force is generated in the standby state and extra pressure is required to lower the piston rod 58. Thus, in this embodiment, the length of each tensile spring 55 at the standby position is set to be its natural length or slightly longer than its natural length. In particular, making the tensile spring 55 slightly longer than the natural length makes it possible to stabilize the extension and contraction operation. From this perspective, it is favorable to set the length of the tensile spring 55 at the standby position to be, for example, 1.2 times or less of the natural length, and more favorable to set the length to be 1.1 times or less.

As shown in FIG. 7A, the warpage correction portion 53 includes the plurality of pushers 61, the support frame 60, the intermediate frame 62, and tilt adjustment portions 63.

The plurality of pushers 61 are columnar members that come into contact with the front side of the workpiece W. Since the tip surfaces of the pushers 61 come into contact with the workpiece W, a force to press the workpiece W against the workpiece stage 30 is dispersed. This makes it possible to avoid breakage of the workpiece W, for example. In addition, a recessed structure may be provided to the tip surface of the pusher 61. This makes it possible to easily check the degree of exhaustion of the pusher 61 (the degree of wear and crushing) visually or by palpation. For example, a plastic material, a rubber material, or the like may be used as the pusher 61 as appropriate. In addition, the shape, material, and the like of the pusher 61 are not limited.

The support frame 60 is a structural member that supports the plurality of pushers 61. Here, a rectangular plate member having the substantially same shape and size as the workpiece W is used as the support frame 60. Note that the support frame 60 is hollowed out as appropriate to reduce weight. The plurality of pushers 61 are disposed in a row at predetermined intervals on the lower surface of the support frame 60 along its four end sides. Note that the pushers 61 arranged along each end side may be unitized such that the pushers 61 are interchangeable on a row-by-row basis.

The intermediate frame 62 is a structural member that supports the support frame 60 via the tilt adjustment portions 63. Here, a rectangular plate member smaller than the support frame 60 is used as the intermediate frame 62. The tilt adjustment portions 63 are respectively provided to the inside of the four apices of the intermediate frame 62 so as to penetrate the intermediate frame 62. The four tilt adjustment portions 63 are connected to the upper surface of the support frame 60 under the intermediate frame 62.

In addition, as shown in FIG. 8A, the lower end of the piston rod 58 is connected to the center of the upper surface of the intermediate frame 62 (at the intersection with the central axis C). In addition, four spring posts 73 are disposed to be rotationally symmetric to the center of the intermediate frame 62 at intervals of 90° on the upper surface of the intermediate frame 62. Note that each spring post 73 is disposed on a line passing through the center of the intermediate frame 62 and parallel to the end side. In addition, four shafts 83 of the guide portion 80 to be described later are connected to the upper surface of the intermediate frame 62.

The tilt adjustment portion 63 is a mechanism for adjusting the tilt of the support frame 60. In this embodiment, the intermediate frame 62 and the support frame 60 are connected by the four tilt adjustment portions 63. Each tilt adjustment portion 63 is configured to be capable of changing a distance between the intermediate frame 62 and the support frame 60 by turning a screw, for example. This makes it possible to adjust the posture of the support frame 60 (tilt with respect to the XY plane). Providing the tilt adjustment portions 63 makes it possible to, for example, cause the plurality of pushers 61 provided to the lower surface of the support frame 60 to come into contact with the workpiece W without bias, thereby making it possible to perform the pressing operation properly.

The guide portion 80 is a mechanism that causes the warpage correction portion to slide relative to the support described above along the moving direction of the piston rod. As shown in FIG. 7A, the guide portion 80 includes a plurality of guides 82, a plurality of shafts 83, and a shaft connecting plate 84. Of those, the plurality of shafts 83 and the shaft connecting plate 84 correspond to a movable portion that moves along with vertical movement of the piston rod 58.

The plurality of guides 82 are cylindrical members that guide the shafts 83 to be described later. Here, four guides 82 are provided to the inside of the four apices of the support plate 75 described above. Each guide 82 is disposed such that its central axis is parallel to the Z-direction and penetrates the support plate 75. In such a manner, the support plate 75 functions as a guide fixing plate that fixes the plurality of guides 82 in the guide portion 80.

The plurality of shafts 83 are columnar members that pass through the guides 82. In addition, the shaft connecting plate 84 is a rectangular plate member for fixing the upper ends of the plurality of shafts 83. Here, four shafts 83 are provided corresponding to the four guides 82. The outer diameter of the shaft 83 is set slightly smaller than the inner diameter of the guide 82 such that the shaft 83 slides inside the guide 82. The lower ends of the four shafts 83 are connected to the upper surface of the intermediate frame 62, and the upper ends thereof are connected to the lower surface of the shaft connecting plate 84.

For example, when the piston rod 58 is lowered as shown in FIG. 7B (or FIG. 8B), the four shafts 83 and the shaft connecting plate 84 are lowered together with the intermediate frame 62. At that time, the moving direction of each shaft 83 is limited to the Z-direction by the guide 82 fixed to the support plate 75. In other words, it is possible to guide the warpage correction portion 53 such that its moving direction is along the Z-direction.

In particular, in a configuration in which a single air cylinder 52 is used as the drive portion of the pressing mechanism 50 as in this embodiment, there is a possibility that the piston rod 58 may rotate or a driving direction of the piston rod 58 may wobble. In this regard, providing the guide portion 80 configured as described above makes it possible to avoid misalignment and the like associated with the rotation or wobbling of the piston rod 58. This can enhance the accuracy of the pressing operation. In addition, providing the guide portion 80 stabilizes the movement of the piston rod 58, so that the number of multiple tensile springs 55 can be reduced, for example. This also allows, for example, a configuration using a single tensile spring 55 as the tensile portion 54.

### Workpiece Stage

As shown in FIGS. 7A and 7B, the workpiece stage 30 includes a workpiece suction stage 38 and a seal member 32. The workpiece suction stage 38 is a vacuum suction stage on which the workpiece W is placed, and includes a plurality of vacuum suction holes (not shown). The workpiece suction stage 38 corresponds to a suction portion 31, which has been described with reference to FIG. 1. Here, a rectangular stage having the substantially same shape and size as the workpiece W is configured. In addition, the suction surface of the workpiece suction stage 38 is formed of, for example, a suction plate including vacuum suction holes. This makes it possible to change the arrangement of the vacuum suction holes according to the type of workpiece W, for example.

The seal member 32 is disposed so as to overlap with the circumferential portion of the workpiece W. Additionally, the seal member 32 is configured such that its upper end is located higher than the surface (suction surface) of the workpiece suction stage 38. Therefore, the circumferential portion of the workpiece W is pressed against the seal member 32 while the seal member 32 is compression-deformed. For example, the plurality of pushers 61 of the warpage correction portion 53 press the circumferential portion of the workpiece W from immediately above the seal member 32. This makes it possible to cause the circumferential portion of the workpiece W to reliably come into contact with the seal member 32, thereby efficiently performing vacuum evacuation.

### Clamp Mechanism

As shown in FIGS. 7A and 7B, the clamp mechanism 40 includes a plurality of clamp portions 41 and clamp drive portions 42 that drive the respective clamp portions 41. The clamp mechanism 40 is a mechanism that clamps the workpiece W so as to prevent the workpiece W from peeling off by a reaction force of the warpage of the workpiece W during the vacuum suction for the workpiece W by the workpiece stage 30, for example.

In this embodiment, the clamp portions 41 are disposed along the four end sides of the workpiece stage 30 (workpiece W). The clamp portion 41 is a plate-like member in which notches 43 are formed to surround the plurality of pushers 61. Here, in order to press the rectangular workpiece W, a longitudinal plate-like member extending along the end side of the workpiece W is used as the clamp portion 41. In this case, notches 43 (here, semicircular notches) in which the plurality of pushers 61 can be respectively located are formed in a longitudinal end side of the clamp portion 41, the end side facing the inner side of the workpiece stage 30.

Additionally, the portions sandwiched by the adjacent notches 43 are contact ends that come into contact with the workpiece W. This makes it possible for the clamp portion 41 to press regions, located between the adjacent pushers 61, in the circumferential portion of the workpiece W, by the contact ends. Note that the shape or the like of the notches 43 is not limited, and for example, a rectangular notch, a triangular notch, and the like may be formed.

The clamp drive portion 42 is a drive mechanism that is connected to each of the clamp portions 41 and performs the opening and closing operation of the connected clamp portion 41. Here, a mechanism that opens and closes the clamp portion 41 by rotating the clamp portion 41 is used. Any mechanism including a pneumatic actuator, an electric actuator, or the like can be used as the clamp drive portion 42. The operation of the clamp drive portion 42 is controlled, for example, by a control apparatus that controls the operation of the entire exposure apparatus 100.

As described above, the clamp mechanism 40 has a function of pressing the workpiece W so as to prevent the workpiece W from peeling off by a reaction force of the warpage of the workpiece W after the workpiece W is vacuum-suctioned by the workpiece stage 30. For example, the workpiece W is held with the clamp mechanism 40 being closed during an exposure process. Alternatively, when the workpiece W can be properly vacuum-suctioned, the clamp portion 41 may be opened to hold the workpiece W by only a vacuum suction force during an exposure process. However, if the warpage of the workpiece W is about 6 mm, the clamp mechanism 40, which presses the workpiece W by rotating the clamp portion 41, swings idly and fails to catch an end portion of the workpiece W.

In contrast, in this embodiment, after the workpiece W is placed on the workpiece stage 30, the pressing operation by the pressing mechanism 50 is performed. At the timing when the pressing operation is being performed, the clamp operation by the clamp mechanism 40 is then performed. Note that when the workpiece W can be vacuum-suctioned properly with the warpage being corrected by the pressing operation, the clamp operation may be performed after the warpage correction portion 53 is retracted. In any case, the clamp operation can be performed with the warpage of the workpiece W being corrected in advance. This makes it possible to avoid a situation in which the clamp portion 41 fails to clamp the workpiece W. This makes it possible to hold the workpiece W properly during the exposure process or the like.

Hereinabove, in the pressing mechanism 50 according to this embodiment, the warpage correction portion 53, which corrects the warpage of the workpiece W placed on the workpiece stage 30 from above, is driven by the piston rod 58 of the air cylinder 52. In addition, the pressing mechanism 50 includes the tensile springs 55 (tensile portion 54) that generate a tensile force 4 between the support 51 (top plate 70), to which the cylinder main body 56 of the air cylinder 52 is fixed, and the warpage correction portion 53. This makes it possible to reduce the load 3 of the warpage correction portion 53 and the piston rod 58, which acts on the workpiece W in addition to the thrust of the air cylinder 52. As a result, it is possible to suitably control the warpage correcting force 1 applied to the workpiece W.

For example, as described with reference to FIG. 3, in the configuration of the comparative example using only the air cylinder 52 as a drive mechanism that presses the warpage correction portion 53 against the workpiece W, the self-weight of the movable portion including the warpage correction portion 53 is also added to the warpage correcting force 1. In other words, it is difficult to press the workpiece W with a force equal to or smaller than the weight of the movable portion. Therefore, for example, there has been a risk that a thin workpiece W would be damaged due to an excessive warpage correcting force 1.

As a method of reducing the weight of the movable portion, for example, the warpage correction portion 53 may be divided into smaller sections and each section may be equipped with an air cylinder 52 to reduce the self-weight of the warpage correction portion, but this method may increase manufacturing costs and worsen maintainability due to the complex structure.

In the pressing mechanism 50 according to this embodiment, the warpage correction portion 53 is pressed against a workpiece W from above, the workpiece W having warpage and being placed on the workpiece stage 30, so that the warpage of the workpiece W is corrected. In the pressing mechanism 50, a single air cylinder 52 is used as the drive mechanism for the warpage correction portion 53, thus allowing the warpage correcting force 1 to be easily variable despite its simple structure. Further, providing the plurality of tensile springs 55 suppresses the load 3 of the movable portion including the warpage correction portion 53. This makes it possible, for example, to achieve a relatively small warpage correcting force 1 that is equal to or less than the weight of the movable portion. As a result, it is possible to generate a warpage correcting force 1 that is appropriate for the type of workpiece W and to satisfactorily avoid damage or the like to the workpiece W.

### Other Embodiments

The present invention is not limited to the embodiment described above and can achieve various other embodiments.

The above embodiment has mainly described the case where a single air cylinder is used, but the present invention is not limited thereto. For example, a plurality of air cylinders may be used to drive the warpage correction portion. In this case as well, a tensile spring or the like is also provided to appropriately cancel out the load of the movable portion including the warpage correction portion and the piston rod of each air cylinder.

In addition, a fluid cylinder other than the air cylinder may also be used. For example, a hydraulic cylinder, a water hydraulic cylinder, or the like may also be used in place of the air cylinder in the above configuration.

The above embodiment has mainly described the example in which a tensile spring connecting the support and the warpage correction portion is used as the tensile portion. For example, a resin material such as rubber may be used instead of the tensile spring. Additionally, for example, a wire extending from the support may be used to suspend the warpage correction portion, and a mechanism that winds up the wire, or the like may be used to generate the tensile force. For example, a spring-driven winding mechanism or a mechanism using a tensile spring can be used. In other mechanisms, the configuration of the tensile portion is not limited as long as the mechanism generates a tensile force between the support and the warpage correction portion along with the lowering of the piston rod.

The above embodiment has mainly described the exposure process of exposing the workpiece W, but the present invention is not limited thereto. The present invention can be applied to any processing performed with the flatness of the workpiece W being maintained. Examples of such processing include a film deposition process of generating a thin film, made of a metal material, a semiconductor material, a resin material, or the like, on the surface of a workpiece W, and an etching process of scraping the surface of the workpiece W. Additionally, the present invention may also be applied to a workpiece stage used in machine processing, laser processing, or the like. In addition to the above, the type of processing is not limited.

At least two of the features among the features described above according to the present technology can also be combined. In other words, various features described in the embodiments may be combined discretionarily regardless of the embodiments. Further, the various effects described above are merely illustrative and not restrictive, and other effects may be exerted.

It should be understood by those skilled in the art that various modifications, combinations, sub-combinations and alterations may occur depending on design requirements and other factors insofar as they are within the scope of the appended claims or the equivalents thereof.

What is claimed is:

1. A pressing mechanism, comprising:
a support disposed above a stage on which a workpiece is placed;
at least one fluid cylinder including
a main body fixed to the support, and
a piston rod that protrudes downward from the main body and moves up and down according to a pressure of a fluid supplied to the main body;
a warpage correction portion that is attached to the piston rod and presses the workpiece against the stage from above by lowering of the piston rod to correct warpage of the workpiece; and
a tensile portion that generates a tensile force between the support and the warpage correction portion along with the lowering of the piston rod.

2. The pressing mechanism according to claim 1, wherein
the tensile portion is configured such that a combined force of a load of a movable portion including the piston rod and the warpage correction portion and the tensile force is zero at a reference position below a standby position of the warpage correction portion with the piston rod being raised.

3. The pressing mechanism according to claim 2, wherein
the reference position is a position at which a lower end of the warpage correction portion reaches a height of a surface of the stage, the height including a thickness of the workpiece.

4. The pressing mechanism according to claim 1, wherein
the tensile portion includes at least one tensile spring that is connected to the support and the warpage correction portion.

5. The pressing mechanism according to claim 4, wherein
the at least one tensile spring includes a plurality of tensile springs, and
the plurality of tensile springs are disposed to be rotationally symmetric to a central axis of the warpage correction portion.

6. The pressing mechanism according to claim 1, wherein
the at least one fluid cylinder includes a single fluid cylinder.

7. The pressing mechanism according to claim 6, further comprising
a guide portion that causes the warpage correction portion to slide relative to the support along a moving direction of the piston rod.

8. The pressing mechanism according to claim 1, wherein
the at least one fluid cylinder includes an air cylinder.

9. A workpiece holding mechanism, comprising:
a stage on which a workpiece is placed; and
a pressing mechanism including
a support disposed above the stage,
at least one fluid cylinder including
a main body fixed to the support, and
a piston rod that protrudes downward from the main body and moves up and down according to a pressure of a fluid supplied to the main body,
a warpage correction portion that is attached to the piston rod and presses the workpiece against the stage from above by lowering of the piston rod to correct warpage of the workpiece, and
a tensile portion that generates a tensile force between the support and the warpage correction portion along with the lowering of the piston rod.

10. A processing apparatus, comprising:
a stage on which a workpiece is placed;
a pressing mechanism including
a support disposed above the stage,
at least one fluid cylinder including
a main body fixed to the support, and
a piston rod that protrudes downward from the main body and moves up and down according to a pressure of a fluid supplied to the main body,
a warpage correction portion that is attached to the piston rod and presses the workpiece against the stage from above by lowering of the piston rod to correct warpage of the workpiece, and
a tensile portion that generates a tensile force between the support and the warpage correction portion along with the lowering of the piston rod; and
a processing section that performs predetermined processing on the workpiece held on the stage.
